(19) United States
(12) Patent Application Publication
(10) Pub. No.: US 2007/0159088 A1
(43) Pub. Date: Jul. 12, 2007

(54) ORGANIC EL COMPONENT

(75) Inventor: Gosuke SAKAMOTO, Kyoto (JP)

Correspondence Address: ROHM CO., LTD.;C/O KEATING & BENNETT, LLP, 8180 GREENSBORO DRIVE, SUITE 850, MCLEAN, VA, 22102, US

(73) Assignee: ROHM CO., LTD., Ukyo-ku, Kyoto (JP)

(21) Appl. No.: 11/617,898

(22) Filed: Dec. 29, 2006

(30) Foreign Application Priority Data
Jan. 11, 2006 (JP) 2006-003940

(51) Int. Cl. H01L 51/52; H01L 51/54

(52) U.S. Cl. 313/506; 428/690; 428/917; 313/504; 428/212

(57) ABSTRACT

An organic EL element includes a positive electrode layer, a hole injection layer, a hole transport layer, a light emitting portion, an electron transport layer, an electron injection layer, and a negative electrode layer laminated on a substrate. The light emitting portion has three first light emitting layers, three hole transport layers, and a second light emitting layer. The three first light emitting layers and the three layer hole transport layers are alternately laminated. The organic EL element is capable of enhancing luminous efficiency and minimizing the attenuation of the luminous efficiency and luminance.

### BACKGROUND OF THE INVENTION

1. Field of the Invention

The present invention relates to an organic EL element having a light emitting portion.

2. Description of the Related Art

An organic EL (electroluminescence) element has a substrate, a positive electrode layer, a hole transport layer, a light emitting layer (light emitting portion) for emitting light, and an electron transport layer or the like. This light emitting layer has been conventionally composed of a single light emitting layer made of a light emitting material such as Alq₃ (trisaluminum) which is a combined body of organic matter and metal.

Holes are injected into the single light emitting layer through the hole transport layer or the like from the positive electrode layer, and electrons are injected through the electron transport layer or the like from the negative electrode layer. The holes and electrons injected into the light emitting layer and confined therein are recombined to emit light in a visible light region.

However, many electrons injected from the negative electrode layer are recombined with the holes existing in the light emitting layer at the interface between the light emitting layer and the negative electrode layer. On the other hand, many holes injected from the positive electrode layer are recombined with the electrons existing in the light emitting layer at the interface between the light emitting layer and the positive electrode layer.

Therefore, since many holes and electrons are recombined only at the interfaces of the light emitting layer, the luminous element at the interfaces of the light emitting layer is deactivated. As a result, although luminous elements existing in the light emitting layer are not deactivated, the deactivation of the luminous elements at the interfaces of the light emitting layer unfortunately causes an increase in the attenuation of the luminous efficiency and luminance.

There has been disclosed a technique in which the holes and the electrons are recombined not only at the interfaces of the light emitting layer but also in the light emitting layer by enhancing the mobility of charges in the light emitting layer to equalize the deactivation of the luminous elements and minimize the attenuation of the luminous efficiency and luminance of the organic EL element.

Specifically, for example, the holes can be easily moved into the light emitting layer by doping NPB (naftelphenylbenzine) which is hardly oxidized, has large mobility for the holes, and is used in the hole transport layer for transporting holes into the light emitting layer. Thereby, since the area in which the luminous elements are deactivated can be dispersed to some extent by promoting the recombination of the holes and electrons not only at the interfaces of the light emitting layer but also in the light emitting layer, the attenuation of the luminous efficiency and luminance of the organic EL element can be minimized. See, for example, Vi-En Choong et al.; “Organic light-emitting diodes with a bipolar transport layer”; APPLIED PHYSICS LETTERS, (U.S.), American Institute of Physics; Jul. 12, 1999; VOLUME 75, NUMBER 2; p. 172.

However, even if the mobility of the holes is enhanced by NPB as described above, only a portion of the holes can be moved into the light emitting layer, and the recombination is mostly carried out at the interfaces of the light emitting layer. Therefore, although the deactivation of the luminous elements at the interfaces of the light emitting layer can be minimized to some extent, it is unlikely that the attenuation of the luminous efficiency and luminance of the organic EL element can be fully minimized using this approach.

### SUMMARY OF THE INVENTION

In order to overcome the problems described above, preferred embodiments of the present invention provide an organic EL element capable of enhancing the luminous efficiency and minimizing the attenuation of the luminous efficiency and luminance.

In accordance with a first preferred embodiment of the present invention, an organic EL element includes a light emitting portion including a plurality of light emitting layers made of a light emitting material, and a plurality of charge transport layers made of a charge transport material capable of smoothly moving either positive or negative charges, wherein the plurality of light emitting layers and charge transport layers are alternately laminated.

In accordance with a second preferred embodiment of the present invention, there is provided an organic EL element as set forth in the first preferred embodiment of the present invention, wherein the light emitting material defining the light emitting layer primarily contains trisaluminum (Alq₃).

In accordance with a third preferred embodiment of the present invention, there is provided an organic EL element as set forth in the first or second preferred embodiments of the present invention, wherein the charge transport layer includes a hole transport material capable of smoothly moving a hole.

In accordance with a fourth preferred embodiment of the present invention, there is provided an organic EL element as set forth in the third preferred embodiment of the present invention, wherein the hole transport material defining the charge transport layer primarily contains naftelphenylbenzine (NPB).

The light emitting portion has a laminated structure in which the plurality of light emitting layers and the plurality of charge transport layers are alternately laminated, and can recombine the holes and the electrons at each of the interfaces between the light emitting layers and the charge transport layers. Thereby, the area in which the holes and the electrons can be recombined can be increased as compared with the case where the light emitting layer is composed of a single layer. Therefore, the luminous efficiency can be enhanced.

The area in which the luminous elements are deactivated can be dispersed by increasing the interface to disperse the area in which the holes and the electrons are recombined. Therefore, the attenuation of the luminous efficiency and luminance can be minimized as compared with the organic EL element having a single light emitting layer in which the deactivation of the luminous element is concentrated.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIG. 1 shows a sectional structure of an organic EL element according to a preferred embodiment of the present invention.

FIG. 2 shows a sectional structure of an organic EL element for comparison.

FIG. 3 is a graph showing the relationship between luminous efficiency and time.

FIG. 4 is a graph showing the attenuation of the luminance of the organic EL element according to a preferred embodiment of the present invention and other organic EL elements for comparison.

### DETAILED DESCRIPTION OF PREFERRED EMBODIMENTS

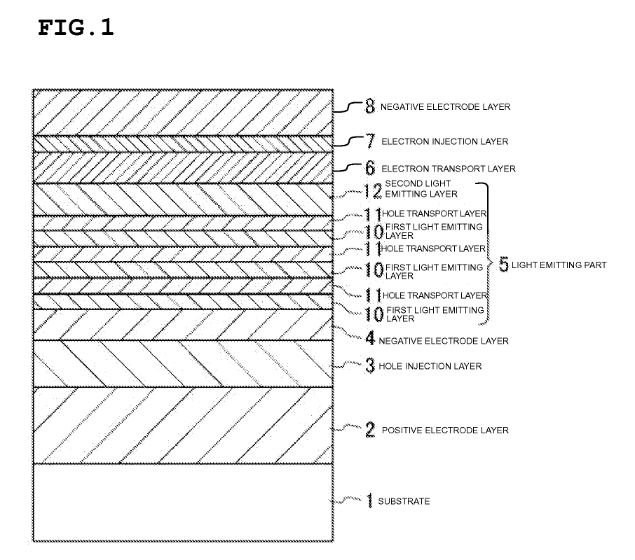

Hereinafter, preferred embodiments of the present invention will be described with reference to the drawings. FIG. 1 shows a sectional structure of an organic EL element according to a preferred embodiment of the present invention.

As shown in FIG. 1, in the organic EL element, a positive electrode layer 2, a hole injection layer 3, a hole transport layer 4, alight emitting portion 5, an electron transport layer 6, an electron injection layer 7, and a negative electrode layer 8 are laminated on a substrate 1.

The light emitting portion 5 has three first light emitting layers 10, three hole transport layers 11, and a second light emitting layer 12. The three first light emitting layers 10 and the three hole transport layers 11 are alternately laminated.

Since this organic EL element is configured to emit light from the side of the substrate 1, a transparent substrate transmitting light such as a glass substrate is used for the substrate 1. Similarly, the positive electrode layer 2 is also composed of a transparent electrode which can transmit light, has a thickness of about 150 nm to about 160 nm and is preferably made of ITO.

The hole injection layer 3 enhances the injection ratio of holes from the positive electrode layer 2. The hole injection layer 3, which is preferably made of copper phthalocyanine (CuPc), has a thickness of about 70 nm. The hole transport layer 4 smoothly transports the holes injected from the positive electrode layer 2 through the hole injection layer 3 to the light emitting portion 5. The hole transport layer 4, which is preferably made of NPB, has a thickness of about 60 nm.

The first light emitting layer 10 of the light emitting portion 5 recombines the injected holes and electrons to emit light. The first light emitting layer 10, into which about 1% of C₅₄₅T as a luminous element is doped, has a thickness of about 2 nm, and is preferably made of Alq₃. The hole transport layer 11 of the light emitting portion 5 smoothly moves the holes injected into the first light emitting layer 10 to another adjacent first light emitting layer 10. The hole transport layer 11, which is preferably made of NPB, has a thickness of about 2 nm. The second light emitting layer 12 of the light emitting portion 5, into which about 1% of C₅₄₅T is doped, is also preferably made of Alq₃ and has a thickness of about 28 nm.

The electron transport layer 6 smoothly transports the electrons injected from the negative electrode layer 8 through the electron injection layer 7 to the light emitting portion 5. The electron transport layer 6, which has a thickness of about 35 nm, is preferably made of Alq₃. The electron injection layer 7 enhances the injection ratio of the electrons from the negative electrode layer 8. The electron injection layer 7, which has a thickness of about 0.5 nm, is preferably made of LiF. The negative electrode layer 8, which has a thickness of about 150 nm, is preferably made of Al.

This organic EL element is manufactured by sequentially forming the positive electrode layer 2; the hole injection layer 3; the hole transport layer 4; the light emitting portion 5 containing the first light emitting layer 10, the hole transport layer 11, and the second light emitting layer 12; the electron transport layer 6; the electron injection layer 7; and the negative electrode layer 8 on the substrate 1 using known manufacturing methods such as a vacuum deposition method.

When a constant voltage is applied between the positive electrode layer 2 and the negative electrode layer 8 in the organic EL element, the holes are injected into the light emitting portion 5 through the hole injection layer 3 and the hole transport layer 4 from the positive electrode layer 2, and the electrons are injected into the light emitting portion 5 through the electron injection layer 7 and the electron transport layer 6 from the negative electrode layer 8. The holes and electrons injected into the light emitting portion 5 are recombined, thereby emitting light.

Herein, since the light emitting portion 5 has a laminated structure in which the three first light emitting layers 10 and the three hole transport layers 11 are alternately laminated in the organic EL element according to the present preferred embodiment, the holes and electrons injected into the light emitting portion 5 can be recombined at each of the interfaces between the three first light emitting layers 10 and the three hole transport layers 11. Thereby, since the recombinable area of the holes and electrons can be increased, the luminous efficiency can be enhanced.

Since the recombinable area of the holes and electrons can be dispersed by increasing the interfaces between the first light emitting layers 10 and the hole transport layers 11, the concentration of the recombination to any of the first light emitting layers 10 of the light emitting portion 5 can be minimized. Therefore, since the quick deactivation of only the luminous elements at any of the interfaces between the first light emitting layers 10 and the hole transport layers 11 can be prevented, the attenuation of the luminous efficiency and luminance can be minimized in the organic EL element according to the present preferred embodiment.

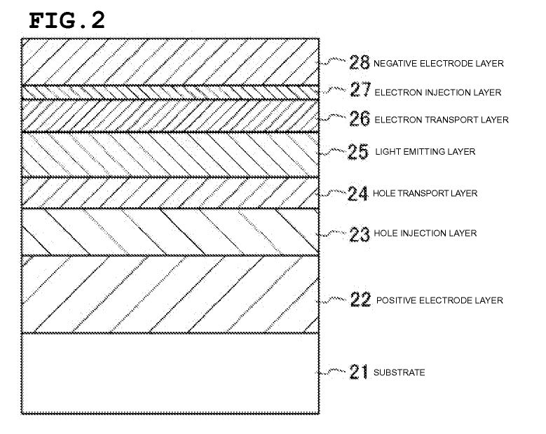

In order to prove the effects of the organic EL element described above, first to fourth organic EL elements produced for comparison with the organic EL element according to the present preferred embodiment described above will be described. FIG. 2 shows a sectional structure of an organic EL element for comparison.

As shown in FIG. 2, in the organic EL element for comparison, a positive electrode layer 22, a hole injection layer 23, a hole transport layer 24, a light emitting layer 25, an electron transport layer 26, an electron injection layer 27, and a negative electrode layer 28 are laminated on a substrate 21. The substrate 21, positive electrode layer 22, hole injection layer 23, hole transport layer 24, electron transport layer 26, electron injection layer 27 and negative electrode layer 28 of the organic EL element for comparison respectively correspond to the substrate 1, positive electrode layer 2, hole injection layer 3, hole transport layer 4, electron transport layer 6, electron injection layer 7 and negative electrode layer 8 of the organic EL element of the present preferred embodiment.

The light emitting layer 25 of the organic EL element for comparison, into which about 1% of C₅₄₅T is doped, has a thickness of about 40 nm, and is made of Alq₃. In the first organic EL element for comparison of the first to fourth organic EL elements for comparison, NPB is not doped into the light emitting layer 25. In the second to fourth organic EL elements for comparison, 1%, 5%, and 10% of the NPB are respectively doped into the light emitting layer 25.

First, with reference to Table 1, the luminous efficiencies of the organic EL element according to the present preferred embodiment and the first to fourth organic EL elements for comparison will be described. Table 1 shows the luminous efficiencies at the time of starting the organic EL elements.

TABLE 1

| | Luminous efficiency |
|---|---|
| | (cd/A) |
| Organic EL element of the present | 11.0 |
| preferred embodiment | |
| First organic EL element for comparison | 9.4 |
| Second organic EL element for | 7.6 |
| comparison | |
| Third organic EL element for comparison | 6.8 |
| Fourth organic EL element for | 6.2 |
| comparison | |

As shown in Table 1, the luminous efficiency of the organic EL element according to the present preferred embodiment is high at 11.0 cd/A. The luminous efficiencies of the first and fourth organic EL elements for comparison are respectively lower at 9.4 cd/A, 7.6 cd/A, 6.8 cd/A, and 6.2 cd/A than that of the organic EL element according to the present preferred embodiment.

This is because the holes or electrons passing without being recombined in any of the first light emitting layers 10 can be recombined at the interfaces between the other first light emitting layers 10 and the hole transport layers 11 by using the laminated structure in which the three first light emitting layers 10 and the three hole transport layers 11 are periodically laminated for the organic EL element according to the present preferred embodiment. That is, since the area in which the holes and the electrons are recombined is increased, it is believed that the luminous efficiency of the present preferred embodiment is enhanced as compared with those of the first to fourth organic EL elements for comparison.

Also, these results show that the luminous efficiency is reduced as the amount of the dopants of the NPB is increased in the second to fourth organic EL elements for comparison. This is because the rate of the holes passing the light emitting layer 25 without being recombined with the electrons in the light emitting layer 25 of the holes injected into the light emitting layer 25 is increased since the mobility of the holes is increased as the amount of the dopants of the NPB is increased.

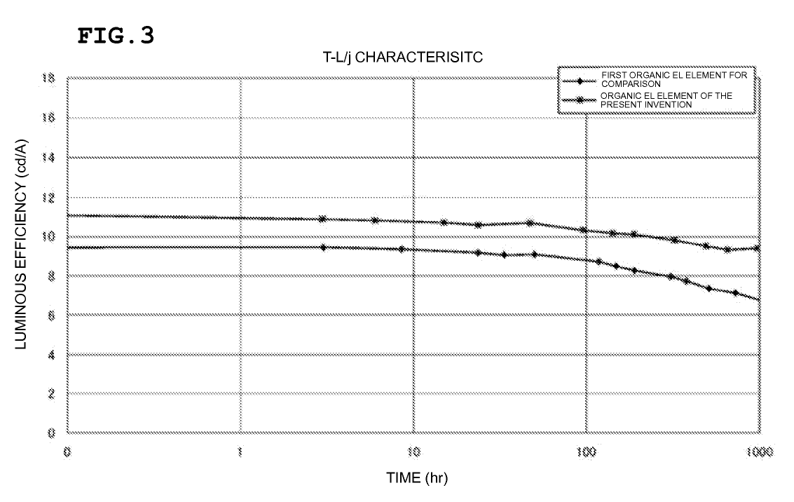

The attenuation rates of the luminous efficiencies of the organic EL element according to the present preferred embodiment and the first organic EL element for comparison will be described with reference to FIG. 3. In FIG. 3, a vertical axis shows luminous efficiency (cd/A), and a horizontal axis shows a time (hr).

As shown in FIG. 3, the luminous efficiency of the organic EL element according to the present preferred embodiment is 9.32 cd/A after 1000 hours. On the other hand, the luminous efficiency of the first organic EL element for comparison is 6.75 cd/A after 1000 hours. These show that, referring to the attenuation rate after 1000 hours with respect to the starting time (0 hour), the attenuation rate of the organic EL element according to the present preferred embodiment is 16%, and the attenuation rate of the first organic EL element for comparison is 28%. The result shows that the attenuation rate of the organic EL element according to the present preferred embodiment is reduced as compared with that of the first organic EL element for comparison.

Although not shown, when the attenuation rate of the luminous efficiency of the organic EL element according to the present preferred embodiment after 200 hours is compared with the attenuation rate of the luminous efficiency of the second organic EL element for comparison into which 1% of the NPB is doped, the attenuation rate of the organic EL element according to the present preferred embodiment is 9.0%. On the other hand, the attenuation rate of the second organic EL element for comparison is 12%. This shows that the attenuation rate of the luminous efficiency of the organic EL element according to the present preferred embodiment is lower than that of the second organic EL element for comparison into which 1% of the NPB is doped.

Since the light emitting layer 25 is composed of a single layer in the first and second organic EL elements for comparison, the recombination of the electrons and holes is concentrated at the interfaces of the single light emitting layer 25, and thereby the deactivation of the luminous element of the light emitting layer 25 is concentrated at the interfaces to increase the attenuation rate of the luminous efficiency.

On the other hand, since the three first light emitting layers 10 and the three hole transport layers 11 are laminated in the organic EL element according to the present preferred embodiment, thereby increasing the number of the interfaces between the first light emitting layers 10 and hole transport layers 11, the recombination of the electrons and holes can be dispersed to the interfaces between the first light emitting layers 10 and the hole transport layers 11. Thereby, since the area in which the luminous element of the first light emitting layer 10 is deactivated can be dispersed, the attenuation rate of the luminous efficiency of the organic EL element of the present preferred embodiment can be minimized.

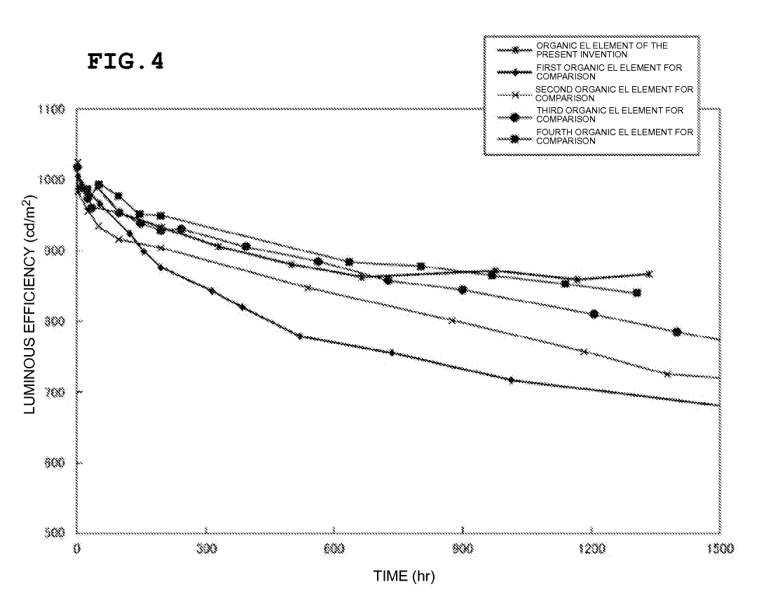

The attenuation of the luminance of the organic EL element according to the present preferred embodiment and the first organic EL element for comparison will be described with reference to FIG. 4. In FIG. 4, a vertical axis shows luminance (cd/m²), and a horizontal axis shows time (hr).

As shown in FIG. 4, the luminance at the time of starting (0 hour) of the organic EL element according to the present preferred embodiment is about 1025 cd/m², and the luminance after about 1000 hours is about 870 cd/m². On the other hand, the luminance at the time of starting of the first organic EL element for comparison is about 1000 cd/m², and the luminance after about 1000 hours is about 720 cd/m².

This shows the attenuation rate after about 1000 hours of the organic EL element according to the present preferred embodiment is about 15%. On the other hand, the attenuation rate of the first organic EL element for comparison is about 28%. This result shows that the attenuation rate of the organic EL element of the present preferred embodiment is lower than that of the first organic EL element for comparison.

Similarly, when the organic EL element according to the present preferred embodiment is compared with the second organic EL element for comparison, FIG. 4 shows that the attenuation rate of the luminance of the second organic EL element for comparison is clearly larger than that of the organic EL element according to the present preferred embodiment.

Also, as shown in FIG. 4, when the organic EL element according to the present preferred embodiment is compared with the third and fourth organic EL elements for comparison, the attenuation rate of the luminance of the organic EL element according to the present preferred embodiment is slightly larger than that of the third and fourth organic EL elements for comparison until about 650 hours. However, the attenuation of the luminance of the organic EL element of the present preferred embodiment is nearly constant after about 650 hours. On the other hand, the luminances of the third and fourth organic EL elements for comparison are further reduced after about 650 hours.

Thereby, after about 1000 hours, the attenuation rates of the luminances of the third and fourth organic EL elements are larger than that of the organic EL element of the present preferred embodiment. This result shows that the longer the luminescence time of the organic EL element, the attenuation rate of the organic EL element of the present preferred embodiment is smaller than that of the third and fourth organic EL elements.

This is because the area in which the luminous element of the organic EL element of the present preferred embodiment is deactivated can be dispersed as compared with the first to fourth organic EL elements for comparison by laminating the three first light emitting layers 10 and the three hole transport layers 11. This is why the organic EL element of the present preferred embodiment can minimize the attenuation rate of the luminous efficiency.

As described above, the improvement in the luminous efficiency and the minimization of the attenuation of the luminous efficiency and luminance of the organic EL element according to the present preferred embodiment are proved.

As described above, the present invention is described in detail using the above preferred embodiments. However, persons skilled in the art understand clearly that the present invention is not limited to the preferred embodiments described herein. The present invention can be carried out as a modification and variation of the preferred embodiments without departing from the effect and scope of the present invention defined by the claims. Therefore, the description herein only describes an illustration of the present invention, and the description does not limit the present invention in any way. Hereinafter, another preferred embodiment will be described.

For example, the thickness of each of the layers and the material defining each of the layers can be varied.

Also, although a structure in which the three first light emitting layers 10 and three hole transport layers 11 are laminated is described in the light emitting portion 5 of the above preferred embodiment, the number of the layers to be laminated can be suitably varied.

Although the first light emitting layers 10 and the hole transport layers 11 are laminated in the light emitting portion 5 of the above preferred embodiment, the light emitting portion 5 may have a laminated structure in which the plurality of first light emitting layers and the plurality of electron transport layers composed of the material having the high mobility of the electrons are alternately laminated.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. An organic EL element comprising:
a light emitting portion including:
a plurality of light emitting layers made of a light emitting material; and
a plurality of charge transport layers made of a charge transporting material capable of smoothly moving either positive or negative charges; wherein
the plurality of light emitting layers and charge transporting layers are alternately laminated.

2. The organic EL element according to claim 1, wherein the light emitting material defining the light emitting layer contains trisaluminum (Alq₃).

3. The organic EL element according to claim 1, wherein the charge transport layer is made of a hole transporting material capable of smoothly moving a hole.

4. The organic EL element according to claim 3, wherein the hole transporting material defining the charge transport layer contains naftelphenylbenzine (NPB).

5. The organic EL element according to claim 2, wherein the charge transporting layer is made of a hole transporting material capable of smoothly moving a hole.

6. The organic EL element according to claim 1, wherein the plurality of light emitting layers and charge transporting layers includes at least three light emitting layers and at least three charge transporting layers.

7. The organic EL element according to claim 1, wherein the plurality of light emitting layers includes a plurality of first light emitting layers and a second light emitting layer, wherein the second light emitting layer is thicker than each of the first light emitting layers.
